(19) United States
(12) Patent Application Publication
(10) Pub. No.: US 2007/0047287 A1
(43) Pub. Date: Mar. 1, 2007

(54) Method and apparatus for storing a three-dimensional arrangement of data bits in a solid-state body

(75) Inventors: Stefan Hell, Gottingen (DE); Stefan Jakobs, Gottingen (DE); Martin Andresen, Gottingen (DE); Andre-C Stiel, Bochum (DE); Christian Eggeling, Gottingen (DE)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Max-Planck-Gesellchaft zur Forderung der Wissenschaften e.V.

(21) Appl. No.: 11/510,194

(22) Filed: Aug. 25, 2006

(30) Foreign Application Priority Data
Aug. 26, 2005 (DE) DE 102005040671.8

(51) Int. Cl. G11C 11/00

(52) U.S. Cl. 365/129

(57) ABSTRACT

A method which serves for writing a three-dimensional arrangement of data bits to a solid-state body comprises the steps of selecting a protein having fluorescence properties that can be altered by means of an optical write signal; providing the solid-state body made from the protein, the protein being present in the solid-state body in crystalline form; setting a spatial distribution which corresponds to the three-dimensional arrangement of data bits of the fluorescence properties of the protein of the solid-state body by means of the optical write signal.

### REFERENCE TO RELATED APPLICATIONS

This application claims the priority of the German patent application DE 10 2005 040671.8 entitled “Method and apparatuses for storing a three-dimensional arrangement of data bits in a solid-state body”, filed on Aug. 26, 2005.

### FIELD OF THE INVENTION

The invention relates to a method and an apparatus for writing a three-dimensional arrangement of data bits to a solid-state body. The invention furthermore relates to a data store comprising a solid-state body, that is to say a solid-state data store, and also to possible uses of such a data store.

### DESCRIPTION OF THE PRIOR ART

The solid-state data stores that are in use at the present time, such as, for example, so-called hard disks or else compact disks (CDs), have a two-dimensional storage array. In other words, a three-dimensional arrangement of data bits has to be translated into a two-dimensional arrangement before it can be written to the two-dimensional storage array of known solid-state data stores. Moreover, the storage capacity of two-dimensional storage arrays is restricted by the only limited area available in the case of known solid-state data stores. It would be desirable to overcome both disadvantages by providing solid-state data stores comprising three-dimensional storage arrays.

With respect to various GFP-like proteins, that is to say proteins which are such that they are similar to the green fluorescent protein (GFP), it is known that they can be converted from a non-fluorescent state to a fluorescent state by means of an optical signal. In this case, this conversion is possible by means of an optical signal whose wavelength is equal to the wavelength which can be used to excite the fluorescence of the protein into its fluorescent state. However, the intensity of the optical signal required for converting the protein into the fluorescent state is greater than is subsequently required for exciting the fluorescence in this state. Known GFP-like proteins having these properties include the protein asFP595 (also referred to as asCP), which occurs naturally in the sea anemone Anemonia sulcata. The properties outlined here are particularly pronounced in the case of the mutant asFP595-A148S (Konstantin A. Lukyanov et al.: Natural Animal Coloration can be Determined by a Non-Fluorescent Green Fluorescent Protein Homolog”, The Journal of Biological Chemistry, Vol. 275, No. 84, issue dated Aug. 25, 2000, pages 25879 to 25882).

US 2005/0111270 A1 is an optical data store having a polymeric storage layer into which is embedded bacteriorhodopsin, an inherently crystalline retinal protein which occurs in halobacteria, or photo-active yellow protein (PYP). Both of the proteins mentioned are non-toxic and have a photo-inducible anisotropy which can be utilized for writing data bits to the storage layer. The data bits can then be read out again from the storage layer by means of a laser beam serving as a probe.

There is a need for a method and an apparatus for writing a three-dimensional arrangement of data bits to a solid-state body and also a data store comprising a solid-state body in which the three-dimensional arrangement of data bits can be stored in the solid-state body.

### SUMMARY OF THE INVENTION

In one aspect, the invention provides a method for writing a three-dimensional arrangement of data bits to a solid-state body, comprising the steps of selecting a protein having fluorescence properties that can be altered by means of an optical write signal; providing the solid-state body made from the protein, the protein being present in the solid-state body in crystalline form; and setting a spatial distribution which corresponds to the three-dimensional arrangement of data bits of the fluorescence properties of the protein of the solid-state body by means of the optical write signal.

In a further aspect, the invention provides an apparatus for writing a three-dimensional arrangement of data bits to a solid-state body, having a solid-state body, the solid-state body comprising a protein which has fluorescence properties that can be altered by means of an optical write signal and which is present in crystalline form.

In yet another aspect the invention provides a written-to data store comprising a solid-state body made from a protein present in crystalline form, the solid-state body having a spatial distribution of fluorescence properties of the protein that corresponds to the three-dimensional arrangement of data bits.

In yet another aspect, the invention provides a foodstuff having an edible data store comprising a solid-state body made from a protein present in crystalline form, the solid-state body having a spatial distribution of fluorescence properties of the protein which corresponds to the three-dimensional arrangement of data bits.

In yet another aspect, the invention provides a security feature for a document having a data store comprising a solid-state body made from a protein present in crystalline form, the solid-state body having a spatial distribution of fluorescence properties of the protein which corresponds to the three-dimensional arrangement of data bits.

In a final aspect, the invention provides a security feature for a document having a crystal made from a protein which, in the crystal, can be converted from a first, non-fluorescent state to a second, fluorescent state by means of an optical signal having a specific intensity with a specific conversion rate, it being possible for the conversion rate to be detected optically as a response to the optical signal.

Advantageous developments of the invention emerge from the patent claims, the description and the drawings. The advantages of features and of combinations of a plurality of features as mentioned in the introduction to the description are merely by way of example, without these necessarily having to be achieved by embodiments according to the invention. Further features can be gathered from the drawings—in particular from the geometries illustrated and the relative dimensions of a plurality of components with respect to one another and also the relative arrangement and operative connection thereof. The combination of features of different embodiments of the invention or of features of different patent claims is likewise possible in departure from the references back chosen in the patent claims and is hereby suggested. This also relates to such features which are illustrated in separate drawings or are mentioned in the description thereof. These features can also be combined with features of different patent claims. Features mentioned in the patent claims can likewise be omitted for further embodiments of the invention.

### BRIEF DESCRIPTION OF THE DRAWINGS

The invention is explained and described in more detail below on the basis of various preferred embodiments of the novel apparatus and of the novel data store contained therein and of the novel method carried out with the aid thereof.

FIG. 1 shows the basic construction of a first embodiment of the novel apparatus with a right-angled arrangement of a writing and erasing device, on the one hand and a read-out device, on the other hand and

FIG. 2 shows the basic construction of a second embodiment of the novel apparatus, which involves a modification of the embodiment in accordance with FIG. 1.

FIG. 3 shows the basic construction of a third embodiment of the novel apparatus with mutually separate writing, erasing and read-out devices.

FIG. 4 shows the basic construction of a coaxial arrangement of a writing device, on the one hand, and a read-out device separate therefrom, on the other hand; and

FIG. 5 shows the basic construction of a fifth embodiment of the novel apparatus with a combined writing and read-out device.

### DETAILED DESCRIPTION OF THE INVENTION

In the case of the novel method for writing a three-dimensional arrangement of data bits to a solid-state body, the solid-state body is provided made from a protein which has fluorescence properties that can be altered by means of an optical write signal and which is present in crystalline form. The solid-state body made from such a crystalline protein makes it possible to set a spatial distribution, which corresponds to the three-dimensional arrangement of data bits—of the fluorescence properties of the protein in the solid-state body by means of the optical write signal. In other words, the storage matrix available in the solid-state body is three-dimensional. Therefore, not only does it enable the direct writing of three-dimensional arrangements of data bits, but the storage capacity is quite fundamentally and dramatically extended by the third dimension of the storage array. It must be regarded as surprising here that solid-state bodies made from proteins which have fluorescence properties that can be altered by means of an optical write signal are actually available in crystalline form in order to be able to form a solid-state body. It has been found, however, that it is possible to produce such crystals made from proteins which are already known for fluorescence properties that can be altered by means of an optical write signal, without this capability of altering their fluorescence properties being lost.

In particular, in the case of the novel method, it is possible to provide the solid-state body made from a protein which can be converted from a non-fluorescent state to a fluorescent state by means of a write signal. The opposite case of targeted local elimination of the fluorescent state by means of the optical write signal is also possible. In each of these cases, the spatial distribution—which is set by means of the write signal—of the fluorescence properties of the protein in the solid-state body can be read out by means of a fluorescence microscopy method in a manner known per se.

When setting the spatial distribution of the fluorescence properties of the protein in the solid-state body by means of the optical write signal, it is also possible to have recourse to techniques known from fluorescence microscopy, which are used in that context for example in order to spatially selectively excite a fluorescent dye in a sample with high resolution, and which here enable a high spatial resolution of the set distribution of the fluorescence properties over the solid-state body.

In concrete embodiments of the novel method, the solid-state body is provided made from a protein in the case of which the optical write signal by means of which it can be converted from the non-fluorescent state to the fluorescent state has the same wavelength and can be used to excite its fluorescence in the fluorescent state.

In the case of the novel method, the solid-state body can be provided made from a protein in the case of which the alteration of the fluorescence properties by means of the optical write signal is based on a single photon process. If, by contrast, said alteration is based on a multiphoton process, it is possible to increase the spatial resolution when setting the spatial distribution of the fluorescence properties that corresponds to the three-dimensional arrangement of data bits whilst utilizing the nonlinear dependence of the excitation of a multiphoton process on the light intensity radiated in.

Especially preferred embodiments of the novel method are those in which the solid-state body is provided made from a protein in which the change in the fluorescence properties that is brought about by means of the write signal is reversible. The novel method can thus be carried out multiply in succession using the same solid-state body made from the crystalline protein, in order to write different three-dimensional arrangements of data bits to the solid-state body.

In concrete terms, in the case of the novel method, the solid-state body may be provided made from a protein in which the change in the fluorescence properties brought about by means of the write signal is reversible by means of an optical erase signal. Thus, it is then possible for successively different spatial distributions of the fluorescence properties of the protein in the solid-state body, which correspond to different three-dimensional arrangement of data bits, to be set by means of the optical write signal, the respective preceding spatial distribution being erased beforehand by means of the optical erase signal.

In concrete terms, in the case of the novel method, the solid-state body may be provided made from a protein which is GFP-like. In other words, a solid-state body may be provided for example made from the protein asFP595 or a mutant of said protein, in particular the mutant asFP595A143S. From these proteins, crystals surprisingly can be formed in which the proteins retain their variable fluorescence properties that are known per se.

In the case of the novel method, the solid-state body may be provided as a single crystal or made from small crystals pressed together made from the protein. If the write signal or else the erase signal is to be oriented at crystal axes of the crystalline protein, the formation of the solid-state body as a single crystal is distinctly preferred.

For example, on account of the water of crystallization that is typically incorporated in protein crystals, it is preferred for the purpose of stabilizing the crystalline structure of the solid-state body in the case of the novel method if the solid-state body is provided in a manner immersed in a buffered aqueous medium or in a manner embedded into a solid matrix.

The spatial distribution of the fluorescence properties of the protein in the solid-state body may be set by spatially scanning the solid-state body by means of a modulated localized write signal or by applying a spatially modulated write signal to the solid-state body. In this case, spatially scanning the solid-state body by means of a modulated, localized write signal is to be understood to mean application to the solid-state body at any time in only one or a limited number of individual points. By contrast, applying a spatially modulated write signal to the solid-state body means that the write signal is applied simultaneously to closed two- or three-dimensional regions of the solid-state body, whereby the writing of the three-dimensional arrangement of data bits to the solid-state body can be carried out more rapidly, in principle.

The read-out of the spatial distribution of the fluorescence properties of the protein in the solid-state body may be effected by spatially resolved detection of the fluorescence properties in the solid-state body. In this case, as has already been noted above, it is possible to have recourse to known techniques of fluorescence microscopy in order, for example, to obtain a sufficiently high spatial resolution during the detection of the fluorescence properties.

Typically, in the case of the novel method, excitation light is applied to the solid-state body for the purpose of reading out the fluorescence properties of the protein in the solid-state body. In this case, the excitation light may be localized in order to obtain a spatial resolution showing the detection of the fluorescence properties of the protein in the solid-state body. However, it is also possible for the excitation light to be applied homogeneously to the entire solid-state body and to effect the spatial resolution exclusively in the region of the registering of the fluorescent light from the solid-state body.

In the case of the novel apparatus for writing a three-dimensional arrangement of data bits to a solid-state body, the solid-state body is formed from a protein which has fluorescence properties that can be altered by means of a write signal and is present in crystalline form. These and further details of the novel apparatus have already been explained in connection with the novel method.

The novel written-to data store has a solid-state body made from a protein in crystalline form, the solid-state body having a spatial distribution of fluorescence properties of the protein that corresponds to the three-dimensional arrangement of data bits. The contents of this and further details of the novel data store have also already been explained above in connection with the novel method.

A particularly interesting use of the novel data store consists in the latter being integrated into foodstuffs as an edible data store. In this case, edible means that the data store is non-toxic overall and is broken down biologically as protein in human digestion provided that the protein has not already been denatured beforehand in the event of the foodstuff being heated. It goes without saying that each spatial distribution of fluorescence properties that is specific to the data store up to that point is lost in the context of the protein being broken down or denatured.

A further particularly interesting use of the novel data store consists in the latter being used as a security feature, in particular for a valuable document, such as, for example, a banknote, or an identity or authorization pass, such as, for example an identity card, a driver's license or a credit card. Such a security feature is particularly forgery-proof since counterfeiting it would require reproducing the growth of the crystals made from the protein that form the essential constituent of the security feature with the correct variable fluorescence properties.

The further new security feature is geared to details of the variability of the fluorescence properties of a crystalline protein and it is likewise provided in particular for a valuable document, such as, for example, a banknote, or an identity or authorization pass, such as, for example an identity card, a driver's license or a credit card, and which has a crystal made from a protein which, in the crystal, can be converted from a first, non-fluorescent state to a second, fluorescent state by means of an optical signal having a specific intensity with a specific conversion rate, it being possible for the conversion rate to be detected optically as a response to the optical signal. In the case of the proteins described in greater detail here, typical conversion rates lie within the range of 1 ms to one second, depending on the intensity of the optical signal used. The authenticity of this security feature can be checked by measurement of the conversion rate and comparison with a predefined value, which may be defined in absolute fashion or else by other features of the respective valuable document or identity or authorization pass.

The preferred embodiments of said further novel security feature once again correspond to the preferred embodiments of the novel method.

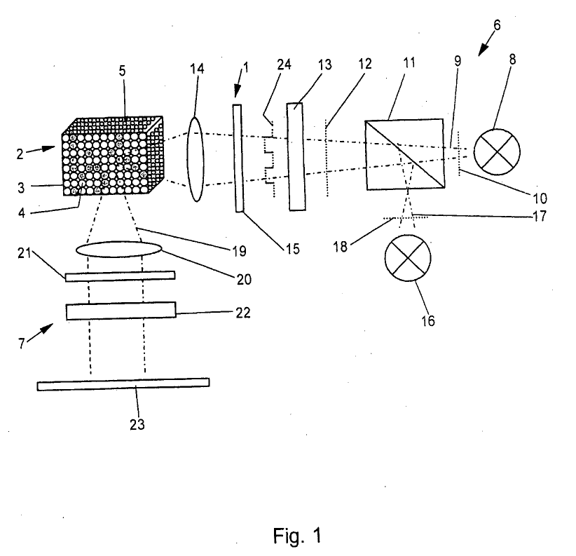

All the apparatuses 1 in accordance with FIGS. 1-5 have a solid-state body 2 which forms the data store 3 of the respective apparatus. The solid-state body 2 comprises crystalline protein 4. In this case, the solid-state body 2 may be composed of small crystals of the protein 4. In particular, the solid-state body 2 may, however, also be a single crystal 5 made from the protein 4, which is indicated diagrammatically in the case of the solid-state body 2 in FIG. 1. The protein 4 which forms the solid-state body 2 in crystalline form is a GFP-like protein. In concrete terms, what is involved here is the A143SA mutant of the protein asFP595, which occurs naturally in the sea anemone Anemonia sulcata. The properties explained below are particularly highly pronounced in the case of the mutant asFP595-A143S. It can be assumed that this also holds true for other mutants of the protein asFP595, which is also referred to as asCP. It is therefore regarded as worthwhile to screen among randomly generated mutants of the protein asFP595 for such proteins having the desired properties. It can furthermore be assumed that other GFP-like proteins, that is to say proteins which are similar to the green fluorescent protein (GFP), will also have these desired properties. These desired properties concern the fact that the protein in a crystalline state can be altered with regard to its optical properties, that is to say here its fluorescence properties, by means of a write signal. In concrete terms, in the case of the proteins specified in greater detail here, it is possible for the protein to be converted from a non-fluorescent state to a fluorescent state by means of the write signal. It is thereby possible to bring about a spatial distribution of fluorescent proteins 4 in the solid-state body 2 in order to store a three-dimensional arrangement of data bits in the data store 3. In this case, the fluorescent state may correspond to a “1” and the non-fluorescent state may correspond to a “0” in the case of the respective data bit, or vice versa. In addition, it is desirable if the protein 4 of the solid-state body 2 can be returned to its original state by means of an erase signal. In the case of the proteins specified in greater detail here, this means a quenching of the fluorescent state by means of an optical erase signal. In the case of GFP-like proteins, said optical erase signal typically lies in the blue range of visible light at a wavelength of approximately 450 nm, while the wavelength of the optical write signal by means of which the protein can be converted to the fluorescence state lies in the green range of visible light, that is to say at a wavelength of approximately 550 nm. The protein can also be excited to fluorescence in its fluorescent state using the same wavelength at approximately 550 nm. However, the requisite intensity of excitation light is significantly lower than the required intensity of the optical write signal having the same wavelength for converting the protein to its fluorescent state, so that the excitation light and the optical write signal can be differentiated on account of their energy density in the region of the respective protein. For converting the protein to its fluorescent state in a manner that can be localized to a greater extent, it is also possible to have recourse to a multiphoton excitation, for example by means of two photons having a doubled wavelength. In this case, the desired higher spatial resolution results from the quadratic dependence of the excitation of a two-photon process on the radiated light intensity.

Crystalline protein having the desired fluorescence properties can be prepared as follows: the purified protein is concentrated by ultrafiltration and taken up for crystallization in 20 mM tris-HCl, pH 7.5/120 nm NaCl to 28 mg/ml. The crystallization of the protein itself can take place overnight by vapor diffusion from a stationary drop using a reservoir containing 20% polyethylene glycol 3.350, 0.2 M tris-HCl (pH 7.1) and 0.3 M NaCl. Crystals of the GFP-like proteins specified in greater detail here contain water of crystallization. To stabilize them it is necessary either to immerse them in buffered aqueous media or to embed them into a stabilizing solid matrix, such as, for example, one composed of polyvinyl alcohol (PVA). If the solid-state body 2 is immersed in a liquid medium for this reason, it is expedient for all the objectives which are parts of the apparatus 1 and face the solid-state body to be adapted thereto, for example by using immersion objectives adapted to the liquid medium.

The apparatus 1 in accordance with FIG. 1 has a writing and erasing device 6 and a read-out device 7 in addition to the data store 3. The writing and erasing device 6 has a light source 8 for emitting the optical write signal 9 for writing to the data store 3. In order to define a desired wavelength for the optical write signal 9, the light source 8 may be monochromatic. As an alternative or in addition, a suitable color filter 10 may be disposed downstream of the light source 8. Behind a beam splitter 11, which permits the optical write signal 9 to pass through, the wavefront 12 of said signal is converted into a modulated wavefront 24 by means of a spatial phase modulator (SPM) 13, which modulated wavefront, after focusing of the optical write signal 9 by means of an objective 14 into the solid-state body 2, leads to a spatial modulation of the intensity distribution of the optical write signal 9 over the solid-state body 2. In addition, a polarization filter 15 is also provided here, which can be used for example to coordinate the polarization of the optical write signal 9 with the spatial orientation of the single crystal 5. As a result of the spatial modulation of the optical write signal 9, over the solid-state body 2, a spatial distribution of regions in which the protein 4 is fluorescent is set therein. This spatial distribution of the fluorescence properties of the protein 4 in the solid-state body 2 can be interpreted as a three-dimensional arrangement of data bits in the solid-state body 2. The storage density that can be achieved in the data store 3 in this case may be greater that 10¹² bits per cm³ volume of the solid-state body 2. In order, after a no longer required distribution of the fluorescence properties of the protein 4 in the solid-state body 2, to set a spatial distribution corresponding to a different three-dimensional arrangement of data bits therein or else in order to convert the solid-state body 2 made from the protein 4 to a defined state prior to the first setting of a distribution of the fluorescence properties of the protein, the writing and erasing device 6 has a further light source 16 for providing an optical erase signal 17 having a specific wavelength that deviates from the wavelength of the write signal 9. For this purpose, too, the light source 16 may be a monochromatic light source which directly provides the desired wavelength of the erase signal 17, or it may be combined with a corresponding color filter 18. In principle, instead of two separate light sources 8 and 16 for the write signal 9, on the one hand, and the erase signal 17, on the other hand, it is also possible to provide a single light source which is combined with a different color filter 10 for providing the write signal 9 and for providing the erase signal 17. For applying the erase signal 17 to the solid-state body 2, the erase signal 17 is coupled into the beam path of the write signal 9 by means of the beam splitter 11. In this case, it is generally not necessary to use the spatial phase modulator (SPM) 13 for the optical erase signal 17 as well, since a homogeneous intensity distribution of the erase signal 17 can be applied to the solid-state body 2.

In order that the distribution of the fluorescence properties of the protein 4 in the solid-state body 2 that is set by means of the writing and erasing device 6 is read out by means of the read-out device 7, it is necessary to excite the fluorescence of the protein 4 in its fluorescent regions. In the case of the GFP-like proteins described in greater detail here, a suitable excitation light for this fluorescence has the same wavelength as that of the optical write signal 9. In other words, the light source 8, if appropriate in conjunction with the color filter 10, is also used for the read-out of the data store 3, although for providing excitation light having a significantly reduced intensity by comparison with the optical write signal 9. Moreover, for the read-out of the data store 3, the excitation light from the light source 8 is applied homogeneously to the solid-state body 2 or the latter is scanned homogeneously by means of the said excitation light, without the spatial distribution of the fluorescence properties of the protein 4 that is set in the solid-state body 2 being taken into consideration. Said spatial distribution of the fluorescence properties is read out from the solid-state body from the excited crystalline protein 4 by means of the read-out device 7. For this purpose, the fluorescent light 19 emitted by the protein 4 passes through an objective 20, a polarization filter 21 and an optical element 22 on to a light sensor array 23, for example, in the form of a known CMOS camera. The polarization filter 21 corresponds in terms of its function to the polarization filter 15 of the writing and erasing device 16. The optical element 22 may have for example a color filter for wavelength-specific selection of the fluorescent light 17 and/or an apertured diaphragm arrangement in order to increase the spatial resolution during the detection of the spatial distribution of the fluorescence properties of the protein 4 in the solid-state body 2 in a manner known per se.

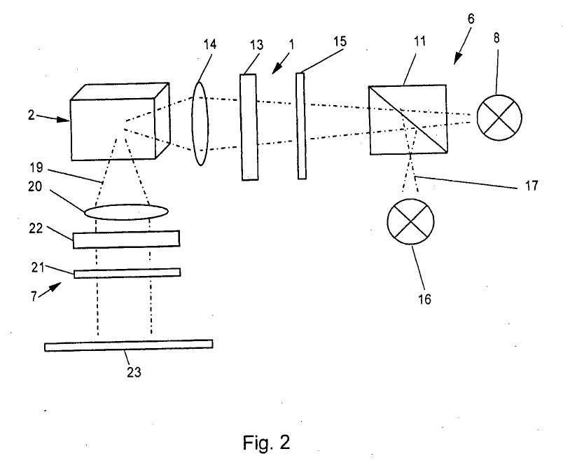

The embodiment of the apparatus 1 in accordance with FIG. 2 differs from that in accordance with FIG. 1 in the following details. Here the solid-state body 2 is not a single crystal 5 made from the protein 4, but rather is composed of small crystals made from the proteins 4. The color filters 10 and 18 have been omitted because the light sources 8 and 16 directly emit the optical write signal 9 and the erase signal 17, respectively with the desired wavelength. The wavefront 12 and the modulated wavefront 24 of the optical write signal 9, said wavefront 24 being modulated by the spatial phase modulator (SPM) 13 are not reproduced diagrammatically. The orders of the spatial phase modulator (SPM) 13 and the polarization filter 15, and respectively of the polarization filter 21 and the optical element 22 have been interchanged in the beam path both of the writing and erasing device 6 and of the read-out device 7 by comparison with FIG. 1. However, the basic functioning of the apparatus 1 in accordance with FIG. 2 is the same as that in accordance with FIG. 1.

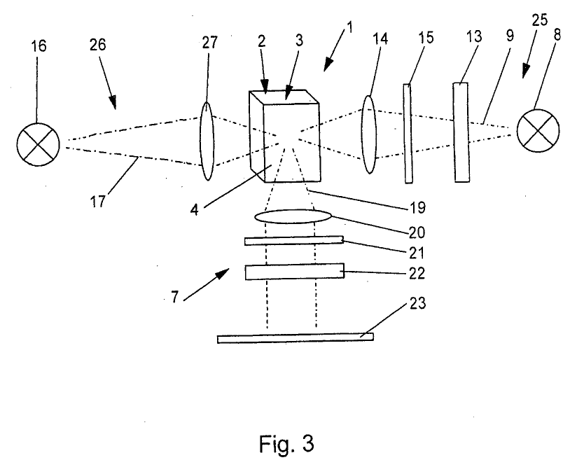

In the case of the embodiment of the apparatus 1 in accordance with FIG. 3, the beam paths of the writing and erasing device 6 in accordance with FIGS. 1 and 2 have been separated into a writing device 25 and an erasing device 26 separate therefrom. Accordingly, the erasing device 26 here has a dedicated objective 27. In addition, even further optical elements may be provided in the beam path of the erasing device 26, said elements not being illustrated here. In principle, however, the function of the apparatus in accordance with FIG. 1 is also identical to that of FIGS. 1 and 2, except that the optical write signal 9 and the erase signal 17 are incident on the solid-state body 2 from mutually opposite directions.

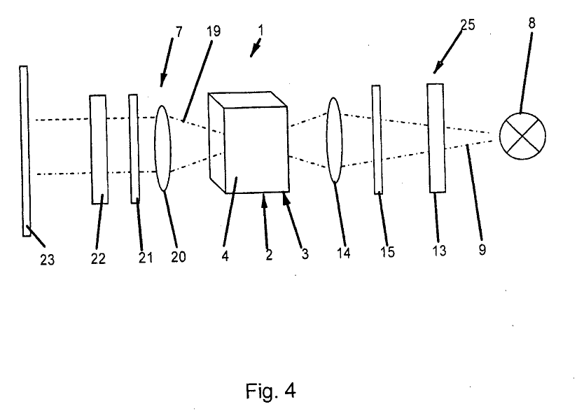

The embodiment of the apparatus 1 in accordance with FIG. 4, differs from that in accordance with FIG. 3 to the effect that the erasing device 26 has been omitted and instead the read-out device 7 is oriented in such a way that its objective 20 is situated opposite the objective 14 of the writing device 25, across the solid-state body 2, so that the read-out device 7 and the writing device 25 are arranged coaxially with respect to one another. An erasing device 26 has been dispensed with here because the protein 4 used here in the solid-state body 2 returns to the non-fluorescent state from a fluorescent state in a foreseeable time solely on account of thermal influences. Repetitions of the write signal 9 nevertheless enable the storage content of the data store 3 to be maintained in a desired manner. If other data are intended to be stored in the data store 3, the solid-state body 2 is simply overwritten by means of a correspondingly changed write signal 9. The previous content of the data store 3 is automatically lost in the process. The need to refresh the content of a data store exists in many conventional semiconductor data memories, too, and is not a specific disadvantage of the data store 3 with the solid-state body 2 made from the protein 4 as described here.

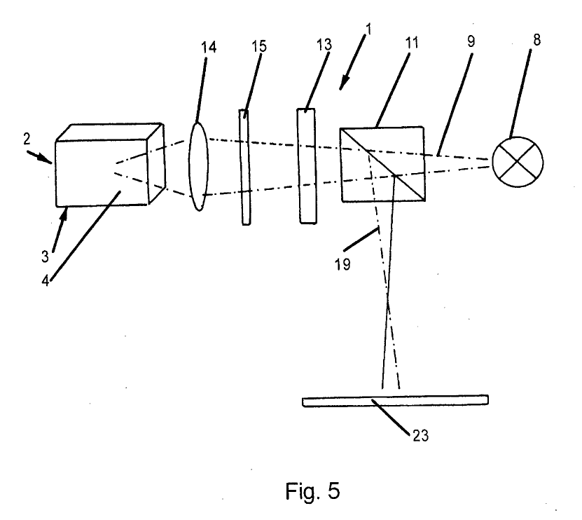

In the case of the apparatus 1 in accordance with FIG. 5 the beam paths of the writing device 25 and of the read-out device 7 in accordance with FIG. 4 are combined, a semitransparent mirror 28 being used in order to deflect the fluorescent light 19 from the beam path of the optical write signal 9 on to the light sensor array 23.

In all of the apparatuses 1 in accordance with FIGS. 1 to 5, the continuous wave lasers, pulsed light sources and, in particular, LEDs and laser diodes are considered as light sources 8 and 16. The spatial phase modulator 13 for modulating the wavefront of the optical light signal 9 can bring about both a two-dimensional intensity distribution of the optical write signal 9 in the solid-state body 2, which is used to scan the volume of the solid-state body 2 and directly a three-dimensional intensity distribution over the volume of the solid-state body 2.

The data carrier 3 of the apparatuses 1 is biodegradable and also biologically consumable. It is therefore possible to integrate it into foodstuffs in order to store data associated with said foodstuffs.

### LIST OF REFERENCE SYMBOLS

1 Apparatus
2 Solid-state body
3 Data store
4 Protein
5 Single crystal
6 Writing and erasing device
7 Read-out device
8 Light source
9 Optical write signal
10 Color filter
11 Beam splitter
12 Wavefront
13 Spatial phase modulator
14 Objective
15 Polarization filter
16 Light source
17 Erase signal
18 Color filter
19 Fluorescent light
20 Objective
21 Polarization filter
22 Optical element
23 Light sensor array
24 Modulated wavefront
25 Writing device
26 Erasing device
27 Objective
28 Semitransparent mirror

1. A method for writing a three-dimensional arrangement of data bits to a solid-state body, comprising the steps of:
selecting a protein having fluorescence properties that can be altered by means of an optical write signal;
providing the solid-state body made from the protein, the protein being present in the solid-state body in crystalline form;
setting a spatial distribution—which corresponds to the three-dimensional arrangement of data bits—of the fluorescence properties of the protein of the solid-state body by means of the optical write signal.

2. The method as claimed in claim 1, a protein being selected which is such that it can be converted from a non-fluorescent state to a fluorescent state by means of the write signal.

3. The method as claimed in claim 2, a protein being selected which is such that the optical write signal by means of which it can be converted from the non-fluorescent state to the fluorescent state has the same wavelength as excitation light which can be used to excite its fluorescence in the fluorescent state.

4. The method as claimed in claim 1, a protein being selected which is such that the alteration of the fluorescence properties by means of the optical write signal is based on a multiphoton process.

5. The method as claimed in claim 1, a protein being selected which is such that the change in the fluorescence properties that is brought about by means of the optical write signal is reversible.

6. The method as claimed in claim 5, a protein being selected which is such that the change in the fluorescence properties that is brought about by means of the optical write signal is reversible by means of an optical erase signal.

7. The method as claimed in claim 6, successively different spatial distributions of the fluorescence properties of the protein in the solid-state body, which correspond to different three-dimensional arrangements of data bits, being set by means of the optical write signal, the respective preceding spatial distribution being erased beforehand by means of the optical erase signal.

8. The method as claimed in claim 1, a protein being selected which is such that it is related to the green fluorescent protein (GFP).

9. The method as claimed in claim 1, a protein being selected which is such that it is a mutant of the protein asFP595.

10. The method as claimed in claim 9, the mutant asFP595-A143S being selected as the protein.

11. The method as claimed in claim 1, the solid-state body being provided made from the protein in such a way that the protein is present in the solid-state body as a single crystal.

12. The method as claimed in claim 1, the solid-state body being provided made from the protein in such a way that the protein is present in the solid-state body in the form of small crystals pressed together.

13. The method as claimed in claim 1, the solid-state body being immersed in a buffered aqueous medium.

14. The method as claimed in claim 1, the solid-state body being embedded into a solid matrix.

15. The method as claimed in claim 1, the spatial distribution of the optical properties of the protein in the solid-state body being set by spatial scanning of the solid-state body by means of a modulated localized optical write signal.

16. The method as claimed in claim 1, the spatial distribution of the optical properties of the protein in the solid-state body being set by applying a spatially modulated optical write signal to the solid-state body.

17. The method as claimed in claim 1, the spatial distribution of the optical properties of the protein in the solid-state body being read out by spatially resolved detection of the optical properties of the protein in the solid-state body.

18. The method as claimed in claim 17, excitation light being applied to the solid-state body for the purpose of reading out the spatial distribution of the optical properties of the protein in the solid-state body.

19. An apparatus for writing a three-dimensional arrangement of data bits to a solid-state body, comprising a solid-state body,
the solid-state body comprising a protein
which has fluorescence properties that can be altered by means of an optical write signal, and
which is present in crystalline form.

20. The apparatus as claimed in claim 19, it being possible for the protein to be converted from a non-fluorescent state to a fluorescent state by means of the optical write signal.

21. The apparatus as claimed in claim 20, the optical write signal by means of which the protein can be converted from the non-fluorescent state to the fluorescent state having the same wavelength as excitation light which can be used to excite a fluorescence of the protein in the fluorescent state.

22. The apparatus as claimed in claim 19, the alteration of the optical properties by means of the optical write signal in the case of the protein being based on a multiphoton process.

23. The apparatus as claimed in claim 19, the change in the optical properties that can be brought about by means of the optical write signal in the case of the protein being reversible.

24. The apparatus as claimed in claim 23, the change in the optical properties that can be brought about by means of the write signal in the case of the protein being reversible by means of an optical erase signal.

25. The apparatus as claimed in claim 19, the protein being related to the green fluorescent protein (GFP).

26. The apparatus as claimed in claim 19, the protein being a mutant of the protein asFP595.

27. The apparatus as claimed in claim 26, the protein being the mutant asFP595-A143S.

28. The apparatus as claimed in claim 19, the solid-state body comprising a single crystal made from the protein.

29. The apparatus as claimed in claim 19, the solid-state body comprising small crystals made from the protein which are pressed together.

30. The apparatus as claimed in claim 19, the solid-state body being immersed in a buffered aqueous medium.

31. The apparatus as claimed in claim 19, the solid-state body being embedded into a solid matrix.

32. The apparatus as claimed in claim 19, a light source that emits the optical write signal furthermore being provided in order to set a spatial distribution—which corresponds to the three-dimensional arrangement of data bits—of the optical properties of the protein in the solid-state body by means of the write signal.

33. The apparatus as claimed in claim 19, provision furthermore being made of a scanning device for spatially scanning the solid-state body by means of a modulated localized optical write signal.

34. The apparatus as claimed in claim 19, provision furthermore being made of a spatial phase modulator for applying a spatially modulated optical write signal to the solid-state body.

35. The apparatus as claimed in claim 19 furthermore being made of a read-out device for reading out the spatial distribution of the optical properties of the protein in the solid-state body by spatially resolved detection of the optical properties of the protein in the solid-state body.

36. The apparatus as claimed in claim 35, the read-out device being assigned a light source for applying excitation light to the protein in the solid-state body.

37. A written-to data store comprising a solid-state body made from a protein present in crystalline form, the solid-state body having a spatial distribution of fluorescence properties of the protein that corresponds to the three-dimensional arrangement of data bits.

38. The data store as claimed in claim 37, the protein being related to the green fluorescent protein (GFP).

39. The data store as claimed in claim 37, the protein being a mutant of the protein asFP595.

40. The data store as claimed in claim 39, the protein being the mutant asFP595-A143S.

41. The data store as claimed in claim 37, the solid-state body comprising a single crystal made from the protein.

42. The data store as claimed in claim 37, the solid-state body comprising small crystals made from the protein which are pressed together.

43. The data store as claimed in claim 37, the solid-state body being immersed in a buffered aqueous medium.

44. The data store as claimed in claim 37, the solid-state body being embedded into a solid matrix.

45. A foodstuff comprising an edible data store comprising a solid-state body made from a protein present in crystalline form, the solid-state body having a spatial distribution of fluorescence properties of the protein which corresponds to the three-dimensional arrangement of data bits.

46. A security feature for a document comprising a data store comprising a solid-state body made from a protein present in crystalline form, the solid-state body having a spatial distribution of fluorescence properties of the protein which corresponds to the three-dimensional arrangement of data bits.

47. A security feature for a document comprising a crystal made from a protein which, in the crystal, can be converted from a first, non-fluorescent state to a second, fluorescent state by means of an optical signal having a specific intensity with a specific conversion rate, it being possible for the conversion rate to be detected optically as a response to the optical signal.

48. The security features as claimed in claim 47, the protein being related to the green fluorescent protein (GFP).
